(19) United States
(12) Patent Application Publication
(10) Pub. No.: US 2021/0327709 A1
(43) Pub. Date: Oct. 21, 2021

(54) METHOD FOR FORMING GATE INSULATOR FILM AND HEAT TREATMENT METHOD

(71) Applicant: SCREEN Holdings Co., Ltd., Kyoto (KR)

(72) Inventors: Hideaki TANIMURA, Kyoto-shi, Kyoto (JP); Takahiro YAMADA, Kyoto-shi, Kyoto (JP)

(21) Appl. No.: 17/270,481

(22) PCT Filed: Jul. 1, 2019
(86) PCT No.: PCT/JP2019/026043

§ 371 Date: Feb. 23, 2021

(30) Foreign Application Priority Data
Aug. 30, 2018 (JP) 2018-161726

(51) Int. Cl. H01L 21/02

(52) U.S. Cl. CPC H01L 21/02345; H01L 21/02175; H01L 21/02164

(57) ABSTRACT

A gate insulator film made of silicon dioxide or gallium oxide is formed on a gallium nitride (GaN) substrate. The GaN substrate is preheated by irradiation with light from halogen lamps, and the surface of the substrate including the gate insulator film is heated to a high temperature for an extremely short time by irradiation with a flash of light from flash lamps. Heating the substrate surface including the gate insulator film in an extremely short heat treatment time prevents the desorption of nitrogen from GaN and makes it possible to reduce the traps existing at the interface between the gate insulator film and GaN without diffusing gallium into the gate insulator film.

### TECHNICAL FIELD

The present invention relates to a gate insulator film forming method for forming a gate insulator film made of silicon dioxide or the like on a gallium nitride (GaN) substrate and a heat treatment method.

### BACKGROUND ART

Gallium nitride based compounds attract attention as light-emitting elements that emit blue light, and are also expected as a basic material for power devices used for power conversion because of their high dielectric breakdown electric field and large energy gap. For example, Patent Document 1 discloses a Metal-Oxide-Semiconductor Field-Effect Transistor (MOSFET) using gallium nitride. In the semiconductor device disclosed in Patent Document 1, a gate insulator film made of silicon dioxide (SiO₂) is formed on a semiconductor layer made of gallium nitride, and an aluminum (Al) gate electrode is further formed on the gate insulator film.

### PRIOR ART DOCUMENT

### Patent Document

Patent Document 1: Japanese Patent Application Laid-Open No. 2015-023074

### SUMMARY

### Problem to be Solved by the Invention

It is known that forming a gate insulator film made of silicon dioxide or the like on a semiconductor layer made of gallium nitride generates a large number of traps at the interface between gallium nitride and the gate insulator film. Since the presence of such traps hinders the movement of carriers and deteriorates the device characteristics, it has been attempted to reduce the number of traps by performing post deposition annealing (PDA).

However, heating gallium nitride to a high temperature desorbs nitrogen, and the unbonded gallium diffuses into the gate insulator film. As a result, the gate insulator film causes deterioration such as an increase in leakage current and a decrease in dielectric breakdown field.

The present invention has been made in view of the above problems, and an object of the present invention is to provide a technique capable of reducing interfacial traps without diffusing gallium in the gate insulator film.

### Means to Solve the Problem

In order to solve the above problems, the first aspect of the present invention is a method for forming a gate insulator film, the method including: a film forming step of forming a gate insulator film made of silicon dioxide or gallium oxide on a substrate made of gallium nitride; and an annealing step of heating the substrate and the gate insulator film for a heat treatment time of 10 ns or more and 100 ms or less.

In addition, in the second aspect, in the method for forming a gate insulator film according to the first aspect, a maximum reaching temperature of the gate insulator film in the annealing step is 800° C. or higher and 1400° C. or lower.

In addition, the third aspect is a heat treatment method including: a loading step of loading a substrate made of gallium nitride on which a gate insulator film made of silicon dioxide or gallium oxide is formed into a chamber; and a light irradiation step of irradiating a surface of the substrate with a flash of light from a flash lamp for an irradiation time of less than 1 second to heat the surface and the gate insulator film.

In addition, in the fourth aspect, in the heat treatment method according to the third aspect, a maximum reaching temperature of the gate insulator film in the light irradiation step is 800° C. or higher and 1400° C. or lower.

In addition, in the fifth aspect, the heat treatment method according to the third or fourth aspect further includes a preheating step of preheating the substrate to 600° C. or higher and 800° C. or lower by light irradiation from a continuously lit lamp before the light irradiation step.

In addition, the sixth aspect is a heat treatment method including: a loading step of loading a substrate made of gallium nitride on which a gate insulator film made of silicon dioxide or gallium oxide is formed into a chamber; and an annealing step of heating the substrate and the gate insulator film for a heat treatment time of 10 ns or more and 100 ms or less.

### Effects of the Invention

According to the method for forming a gate insulator film according to the first and second aspects and the heat treatment method according to the sixth aspect, since the substrate made of gallium nitride and the gate insulator film are heated for a heat treatment time of 10 ns or more and 100 ms or less, the heating time is extremely short, and it is possible to prevent desorption of nitrogen from gallium nitride and to reduce interfacial traps without diffusing gallium into the gate insulator film.

According to the heat treatment method according to the third to fifth aspects, since the surface of the gallium nitride substrate is irradiated with a flash of light from a flash lamp for an irradiation time of less than 1 second and the surface and the gate insulator film are heated, the heating time is extremely short, and it is possible to prevent desorption of nitrogen from gallium nitride and to reduce interfacial traps without diffusing gallium into the gate insulator film.

### BRIEF DESCRIPTION OF DRAWINGS

FIG. 1 is a longitudinal sectional view showing a configuration of a heat treatment apparatus used when the heat treatment method according to the present invention is implemented.

FIG. 2 is a perspective view showing the overall appearance of a holder.

FIG. 3 is a plan view of a susceptor.

FIG. 4 is a cross-sectional view of the susceptor.

FIG. 5 is a plan view of a transfer mechanism.

FIG. 6 is a side view of the transfer mechanism.

FIG. 7 is a plan view showing the arrangement of a plurality of halogen lamps.

FIG. 8 is a flowchart showing a procedure of the method for forming a gate insulator film according to the present invention.

FIG. 9 is a diagram showing a state in which a gate insulator film is formed on the GaN substrate.

FIG. 10 is a diagram showing a state in which the GaN substrate is placed on a mounting plate.

### DESCRIPTION OF EMBODIMENT

Hereinafter, an embodiment of the present invention will be described in detail with reference to the drawings.

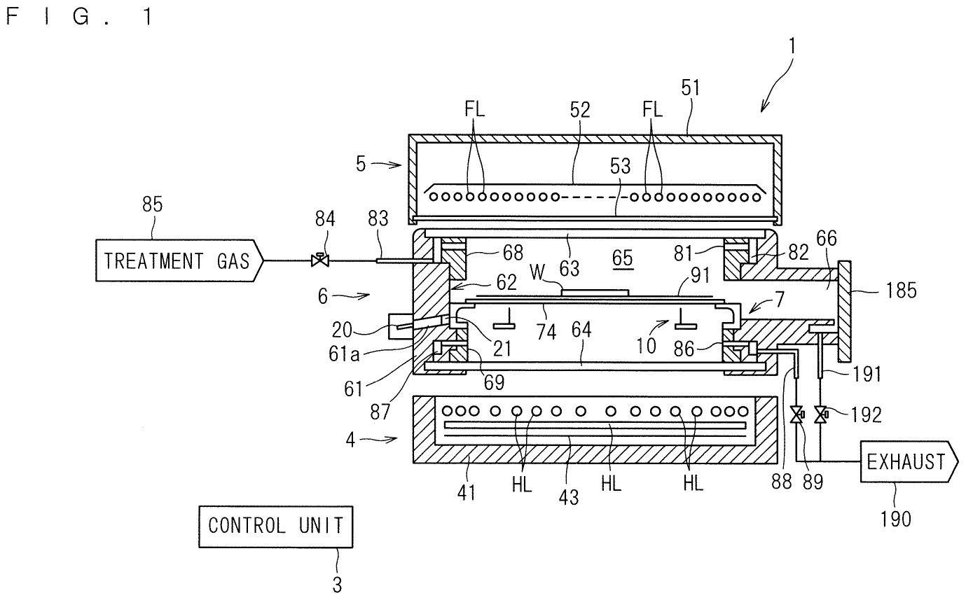

First, a heat treatment apparatus for implementing the heat treatment method according to the present invention will be described. FIG. 1 is a longitudinal sectional view showing a configuration of a heat treatment apparatus 1 used when the heat treatment method according to the present invention is implemented. The heat treatment apparatus 1 in FIG. 1 is a flash lamp annealing apparatus that heats the GaN substrate W by irradiating the gallium nitride substrate (GaN substrate) W with a flash of light. It should be noted that in FIG. 1 and each subsequent drawing, the dimensions and numbers of each part are exaggerated or simplified as necessary for easy understanding.

The heat treatment apparatus 1 includes a chamber 6 for housing the GaN substrate W, a flash heating part 5 incorporating a plurality of flash lamps FL, and a halogen heating part 4 incorporating a plurality of halogen lamps HL. The flash heating part 5 is provided above the chamber 6, and the halogen heating part 4 is provided below the chamber 6. In addition, the heat treatment apparatus 1 includes, inside the chamber 6, a holder 7 for holding a GaN substrate W in a horizontal attitude, and a transfer mechanism 10 for transferring the GaN substrate W between the holder 7 and the outside of the heat treatment apparatus 1. Furthermore, the heat treatment apparatus 1 includes a controller 3 for controlling respective operating mechanisms provided in the halogen heating part 4, the flash heating part 5, and the chamber 6 to cause the operating mechanisms to perform heat treatment on the GaN substrate W.

The chamber 6 is configured by mounting quartz chamber windows above and below the tubular chamber side portion 61. The chamber side portion 61 has a substantially tubular shape with upper and lower openings, an upper chamber window 63 is mounted to block the upper opening, and a lower chamber window 64 is mounted to block the lower opening. The upper chamber window 63 forming the ceiling portion of the chamber 6 is a disc-shaped member made of quartz, and serves as a quartz window that transmits a flash of light emitted from the flash heating part 5 into the chamber 6. In addition, the lower chamber window 64 forming the floor portion of the chamber 6 is also a disc-shaped member made of quartz, and serves as a quartz window that transmits light from the halogen heating part 4 into the chamber 6.

In addition, a reflective ring 68 is mounted on an upper portion of the inner wall surface of the chamber side portion 61, and a reflective ring 69 is mounted on a lower portion thereof. Both reflective rings 68 and 69 are annularly formed. The upper side reflective ring 68 is mounted by being fitted from the upper side of the chamber side portion 61. On the other hand, the lower side reflective ring 69 is mounted by being fitted from the lower side of the chamber side portion 61 and is fastened with screws (not shown). That is, both reflective rings 68 and 69 are detachably mounted on the chamber side portion 61. An inner space of the chamber 6, that is, a space surrounded by the upper chamber window 63, the lower chamber window 64, the chamber side portion 61, and the reflective rings 68 and 69 is defined as a heat treatment space 65.

Mounting the reflective rings 68 and 69 on the chamber side portion 61 forms a recessed portion 62 on the inner wall surface of the chamber 6. That is, the recessed portion 62 is defined which is surrounded by a middle portion of the inner wall surface of the chamber side portion 61 where the reflective rings 68 and 69 are not mounted, a lower end surface of the reflective ring 68, and an upper end surface of the reflective ring 69. The recessed portion 62 is annularly formed along the horizontal direction on the inner wall surface of the chamber 6, and surrounds the holder 7 for holding a GaN substrate W. The chamber side portion 61 and the reflective rings 68 and 69 are made of a metal material excellent in strength and heat resistance (such as stainless steel).

In addition, the chamber side portion 61 is provided with a transport opening (throat) 66 for carrying a GaN substrate W into and out of the chamber 6. The transport opening 66 can be opened and closed by a gate valve 185. The transport opening 66 is connected in communication with an outer peripheral surface of the recessed portion 62. Therefore, when the gate valve 185 opens the transport opening 66, it is possible to carry a GaN substrate W into the heat treatment space 65 through the recessed portion 62 from the transport opening 66 and to carry a GaN substrate W out from the heat treatment space 65. In addition, when the gate valve 185 closes the transport opening 66, the heat treatment space 65 inside the chamber 6 becomes a hermetically sealed space.

Furthermore, a through hole 61a is drilled in the chamber side portion 61. A radiation thermometer 20 is mounted to a portion of the outer wall surface of the chamber side portion 61 where the through hole 61a is provided. The through hole 61a is a cylindrical hole for guiding the infrared light radiated from the lower surface of a mounting plate 91 held by a susceptor 74 described below to the radiation thermometer 20. The through hole 61a is provided to be inclined with respect to the horizontal direction so that its axis in the through direction intersects with the main surface of the susceptor 74. A transparent window 21 made of a barium fluoride material that transmits infrared light in a wavelength range measurable by the radiation thermometer 20 is attached to the end portion on the side facing the heat treatment space 65 of the through hole 61a.

In addition, the upper portion of the inner wall of the chamber 6 is provided with a gas supply opening 81 for supplying the treatment gas to the heat treatment space 65. The gas supply opening 81 is provided at a position above the recessed portion 62, and may be provided in the reflective ring 68. The gas supply opening 81 is connected in communication with the gas supply pipe 83 via a buffer space 82 formed in an annular shape inside the side wall of the chamber 6. The gas supply pipe 83 is connected to the treatment gas supply source 85. In addition, a valve 84 is inserted halfway through the path of the gas supply pipe 83. When the valve 84 is opened, the treatment gas is supplied from the treatment gas supply source 85 to the buffer space 82. The treatment gas flowing in the buffer space 82 flows in a spreading manner within the buffer space 82 lower in fluid resistance than the gas supply opening 81, and is supplied from the gas supply opening 81 into the heat treatment space 65. As the treatment gas, for example, nitrogen (N₂), ammonia (NH₃), or a forming gas which is a mixed gas of hydrogen (H₂) and nitrogen (N₂) can be used.

On the other hand, a gas exhaust opening 86 for exhausting the gas in the heat treatment space 65 is provided in the lower portion of the inner wall of the chamber 6. The gas exhaust opening 86 is provided at a position below the recessed portion 62, and may be provided in the reflective ring 69. The gas exhaust opening 86 is connected in communication with a gas exhaust pipe 88 through a buffer space 87 annularly formed inside the side wall of the chamber 6. The gas exhaust pipe 88 is connected to an exhaust part 190. In addition, a valve 89 is inserted halfway through the path of the gas exhaust pipe 88. When the valve 89 is opened, the gas in the heat treatment space 65 is discharged from the gas exhaust opening 86 through the buffer space 87 to the gas exhaust pipe 88. It should be noted that a plurality of gas supply openings 81 and gas exhaust openings 86 may be provided along the circumferential direction of the chamber 6, or may be slit-shaped. In addition, the treatment gas supply source 85 and the exhaust part 190 may be mechanisms provided in the heat treatment apparatus 1, or may be utilities of a factory in which the heat treatment apparatus 1 is installed.

In addition, a gas exhaust pipe 191 for discharging the gas in the heat treatment space 65 is also connected to the tip of the transport opening 66. The gas exhaust pipe 191 is connected to the exhaust part 190 via a valve 192. Opening the valve 192 exhausts the gas in the chamber 6 through the transport opening 66.

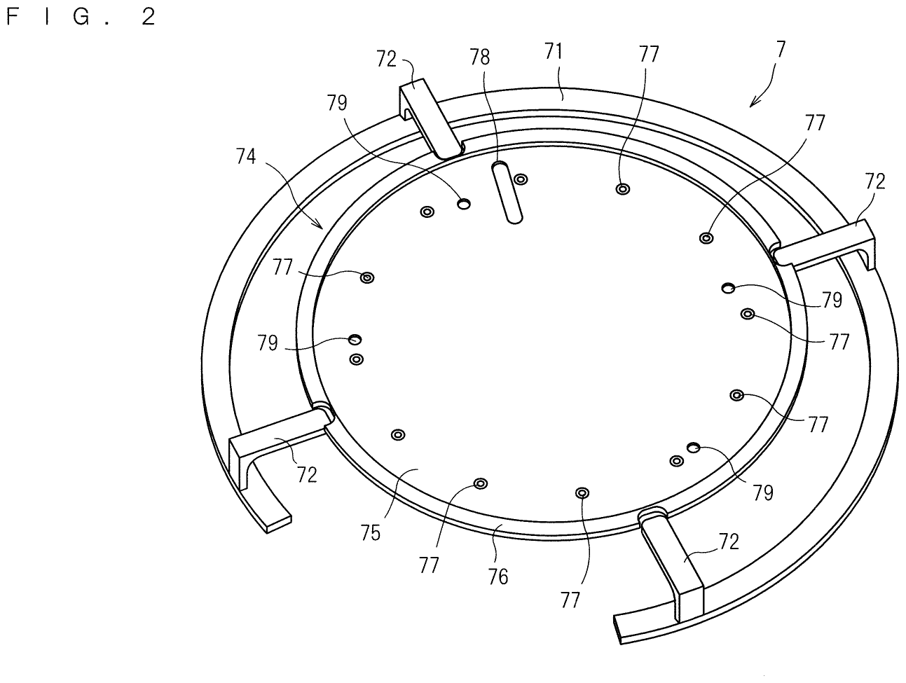

FIG. 2 is a perspective view showing the overall appearance of the holder 7. The holder 7 includes a base ring 71, coupling portions 72, and the susceptor 74. The base ring 71, the coupling portion 72, and the susceptor 74 are all made of quartz. That is, the entire holder 7 is made of quartz.

The base ring 71 is an arc-shaped quartz member in which a part is missing from the annular shape. This missing portion is provided to prevent interference between the transfer arm 11 of the transfer mechanism 10 described below and the base ring 71. Placing the base ring 71 on the bottom surface of the recessed portion 62 causes the base ring 71 to be supported on the wall surface of the chamber 6 (see FIG. 1). On the upper surface of the base ring 71, a plurality of coupling portions 72 (four in the present embodiment) are erected along the circumferential direction of the annular shape thereof The coupling portion 72 is also a quartz member, and is fixed to the base ring 71 by welding.

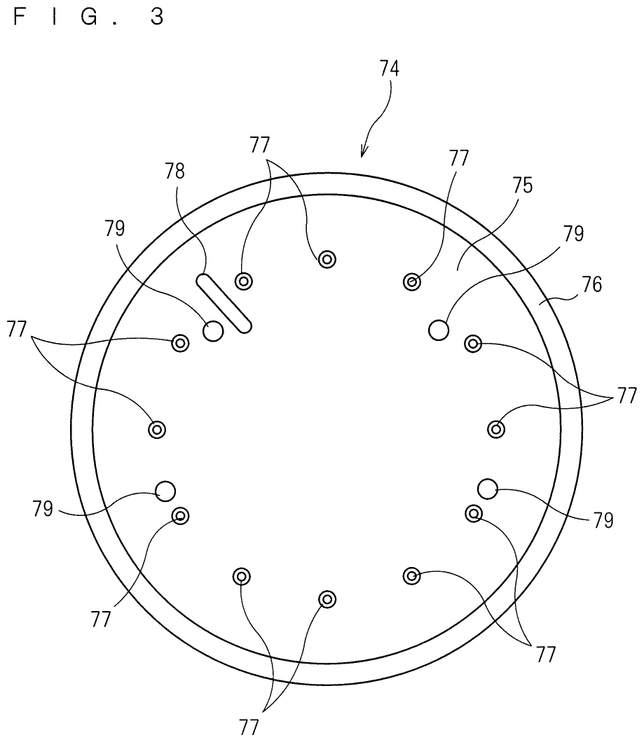

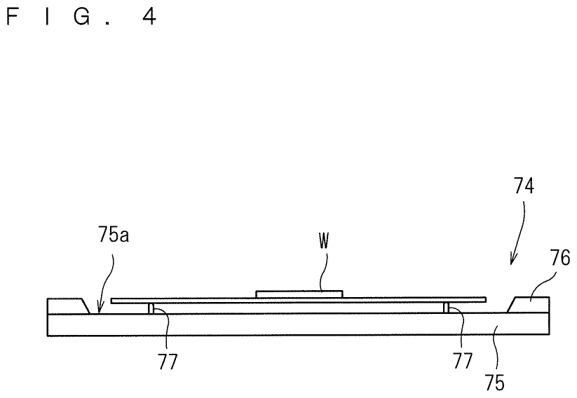

The susceptor 74 is supported by the four coupling portions 72 provided on the base ring 71. FIG. 3 is a plan view of the susceptor 74. In addition, FIG. 4 is a cross-sectional view of the susceptor 74. The susceptor 74 includes a holding plate 75, a guide ring 76, and a plurality of support pins 77. The holding plate 75 is a substantially circular flat plate member made of quartz. The diameter of the holding plate 75 is greater than that of a GaN substrate W. That is, the holding plate 75 has a larger planar size than the GaN substrate W.

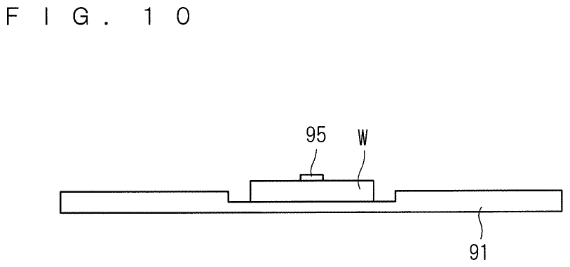

The guide ring 76 is installed on the upper surface circumferential edge portion of the holding plate 75. The guide ring 76 is an annular-shaped member having an inner diameter larger than the diameter of the mounting plate 91 (see FIG. 10) on which the GaN substrate W is placed. For example, when the diameter of the mounting plate 91 is 300 mm, the inner diameter of the guide ring 76 is 320 mm. The inner circumference of the guide ring 76 is a tapered surface so as to widen upward from the holding plate 75. The guide ring 76 is made of quartz similar to the holding plate 75. The guide ring 76 may be welded to the upper surface of the holding plate 75 or fixed to the holding plate 75 with separately machined pins and the like. Alternatively, the holding plate 75 and the guide ring 76 may be machined as an integral member.

On the upper surface of the holding plate 75, the region inside the guide ring 76 serves as a flat holding surface 75a for holding the mounting plate 91 on which the GaN substrate W is placed. A plurality of support pins 77 are erected on the holding surface 75a of the holding plate 75. In the present embodiment, a total of 12 support pins 77 are erected at every 30° along the circumference of the circle concentric with the outer circumference circle (inner circumference circle of the guide ring 76) of the holding surface 75a. The diameter of the circle in which the 12 support pins 77 are arranged (distance between the opposing support pins 77) is smaller than the diameter of the mounting plate 91, and is 270 mm to 280 mm (270 mm in the present embodiment) when the diameter of the mounting plate 91 is 300 mm. Each of the support pins 77 is made of quartz. The plurality of support pins 77 may be provided on the upper surface of the holding plate 75 by welding, or may be machined integrally with the holding plate 75.

Returning to FIG. 2, the four coupling portions 72 erected on the base ring 71 and the circumferential edge portion of the holding plate 75 of the susceptor 74 are fixed by welding. That is, the susceptor 74 and the base ring 71 are fixedly coupled by the coupling portion 72. The base ring 71 of the holder 7 is supported on the wall surface of the chamber 6, whereby the holder 7 is mounted on the chamber 6. In a state where the holder 7 is mounted on the chamber 6, the holding plate 75 of the susceptor 74 is in a horizontal attitude (attitude in which the normal line coincides with the vertical direction). That is, the holding surface 75a of the holding plate 75 is a horizontal plane.

The mounting plate 91 on which the GaN substrate W is placed is placed and held in a horizontal attitude on the susceptor 74 of the holder 7 mounted on the chamber 6. At this time, the mounting plate 91 is supported by the 12 support pins 77 erected on the holding plate 75 and is held by the susceptor 74. More precisely, the upper end portions of the 12 support pins 77 come into contact with the lower surface of the mounting plate 91 to support the mounting plate 91. Since the heights of the 12 support pins 77 (distances from the upper ends of the support pins 77 to the holding surface 75a of the holding plate 75) are uniform, the mounting plate 91 can be supported in a horizontal attitude by the 12 support pins 77.

In addition, the mounting plate 91 is supported by a plurality of support pins 77 at a predetermined distance from the holding surface 75a of the holding plate 75. The thickness of the guide ring 76 is larger than the height of the support pin 77. Therefore, the horizontal positional deviation of the mounting plate 91 supported by the plurality of support pins 77 is prevented by the guide ring 76.

In addition, as shown in FIGS. 2 and 3, in the holding plate 75 of the susceptor 74, an opening 78 vertically penetrating is formed. The opening 78 is provided in order for the radiation thermometer 20 to receive the radiation light (infrared light) radiated from the lower surface of the mounting plate 91. That is, the radiation thermometer 20 receives the light radiated from the lower surface of the mounting plate 91 through the opening 78 and the transparent window 21 mounted on the through hole 61a of the chamber side portion 61, and measures the temperature of the mounting plate 91. Furthermore, in the holding plate 75 of the susceptor 74, four through holes 79 through which the lift pins 12 of the transfer mechanism 10 described below pass are drilled for the transfer of the mounting plate 91.

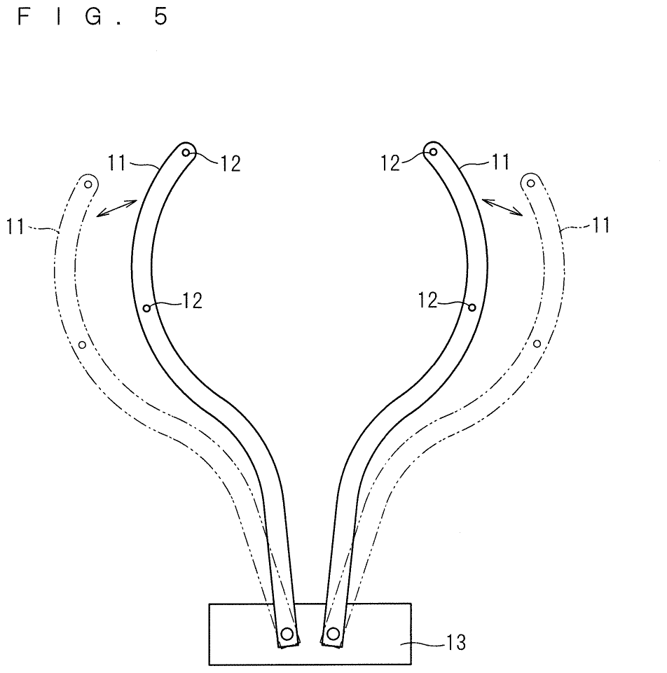

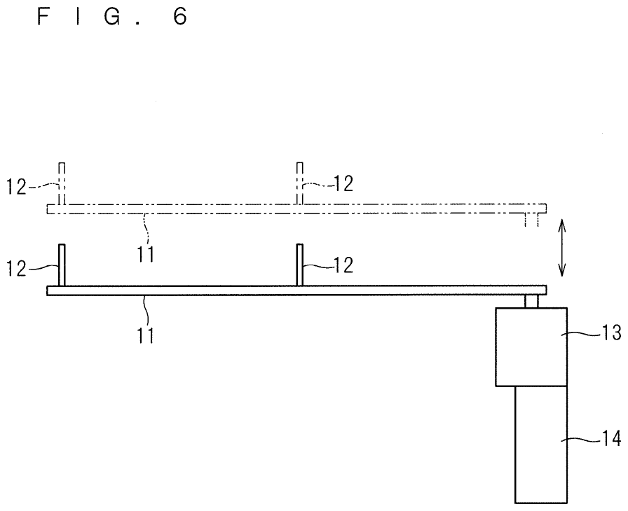

FIG. 5 is a plan view of the transfer mechanism 10. In addition, FIG. 6 is a side view of the transfer mechanism 10. The transfer mechanism 10 includes two transfer arms 11. The transfer arm 11 has an arc shape that approximately follows the annular recessed portion 62. Two lift pins 12 are erected on each transfer arm 11. The transfer arm 11 and the lift pin 12 are made of quartz. Each transfer arm 11 is pivotable by a horizontal movement mechanism 13. The horizontal movement mechanism 13 horizontally moves a pair of transfer arms 11 between the transfer operation position (solid line position in FIG. 5) that transfers the mounting plate 91 with respect to the holder 7 and the retracted position (two-dot chain line position in FIG. 5) that does not overlap with the mounting plate 91 held by the holder 7 in a plan view. The horizontal movement mechanism 13 may be a mechanism that causes separate motors to rotate the respective transfer arms 11, or may be a mechanism that causes a single motor to rotate the pair of transfer arms 11 in an interlocked manner using a link mechanism.

In addition, the pair of transfer arms 11 are moved up and down together with the horizontal movement mechanism 13 by an elevating mechanism 14. When the elevating mechanism 14 raises the pair of transfer arms 11 at the transfer operation position, a total of four lift pins 12 pass through the through holes 79 (see FIGS. 2 and 3) drilled in the susceptor 74, and the upper end of the lift pin 12 protrudes from the upper surface of the susceptor 74. On the other hand, when the elevating mechanism 14 lowers the pair of transfer arms 11 at the transfer operation position to pull out the lift pins 12 from the through holes 79, and the horizontal movement mechanism 13 moves the pair of transfer arms 11 so as to open the pair of transfer arms 11, each transfer arm 11 moves to the retracted position. The retracted position of the pair of transfer arms 11 is directly above the base ring 71 of the holder 7. Since the base ring 71 is placed on the bottom surface of the recessed portion 62, the retracted position of the transfer arm 11 is inside the recessed portion 62. It should be noted that an exhaust mechanism (not shown) is also provided near the portion where the driving unit (horizontal movement mechanism 13 and elevating mechanism 14) of the transfer mechanism 10 is provided, and is configured to discharge the atmosphere around the driving unit of the transfer mechanism 10 to the outside of the chamber 6.

Returning to FIG. 1, the flash heating part 5 provided above the chamber 6 is configured to include a light source including a plurality of (30 in the present embodiment) xenon flash lamps FL inside an enclosure 51 and a reflector 52 provided to cover above the light source. In addition, a lamp light radiation window 53 is mounted on the bottom portion of the enclosure 51 of the flash heating part 5. The lamp light radiation window 53 constituting the floor portion of the flash heating part 5 is a plate-shaped quartz window made of quartz. Installing the flash heating part 5 above the chamber 6 causes the lamp light radiation window 53 and the upper chamber window 63 to face each other. The flash lamps FL apply a flash of light from above the chamber 6 through the lamp light radiation window 53 and the upper chamber window 63 to the heat treatment space 65.

The plurality of flash lamps FL, each of which is a rod-shaped lamp having an elongated cylindrical shape, are arranged in a plane so that the longitudinal directions of the respective flash lamps FL are in parallel with each other along a main surface of a GaN substrate W held by the holder 7 (that is, along a horizontal direction). Therefore, the plane formed by the arrangement of the flash lamps FL is also a horizontal plane. The region where a plurality of flash lamps FL are arranged is larger than the planar size of the GaN substrate W.

The xenon flash lamp FL includes a cylindrical glass tube (discharge tube) in which xenon gas is sealed inside, and an anode and a cathode, which are connected to a capacitor, are arranged at both ends thereof, and a trigger electrode attached on the outer circumferential surface of the glass tube. Since xenon gas is electrically an insulator, electricity does not flow in the glass tube under normal conditions even if electric charges are accumulated in the capacitor. However, when a high voltage is applied to the trigger electrode to break the insulation, electric charges stored in the capacitor flow instantly in the glass tube, and light is emitted by the excitation of xenon atoms or molecules at that time. In this xenon flash lamp FL, the electrostatic energy stored in the capacitor in advance is converted into an extremely short optical pulse of 0.1 ms to 100 ms, so that the xenon flash lamp FL has the feature that it can apply extremely strong light compared to a continuously lit light source such as the halogen lamp HL. That is, the flash lamp FL is a pulse light emitting lamp that emits light instantaneously in an extremely short time of less than 1 second. It should be noted that the light emitting time of the flash lamp FL can be adjusted by the coil constant of the lamp power supply that supplies power to the flash lamp FL.

In addition, the reflector 52 is provided above the plurality of flash lamps FL so as to cover all of them. The basic function of the reflector 52 is to reflect the flashes of light emitted from the plurality of flash lamps FL toward the heat treatment space 65. The reflector 52 is made of an aluminum alloy plate, and its surface (the surface on the side facing the flash lamps FL) is roughened by blasting.

The halogen heating part 4 provided below the chamber 6 incorporates a plurality of halogen lamps HL (40 in the present embodiment) inside an enclosure 41. The halogen heating part 4 heats the GaN substrate W by applying light from below the chamber 6 through the lower chamber window 64 to the heat treatment space 65 with a plurality of halogen lamps HL.

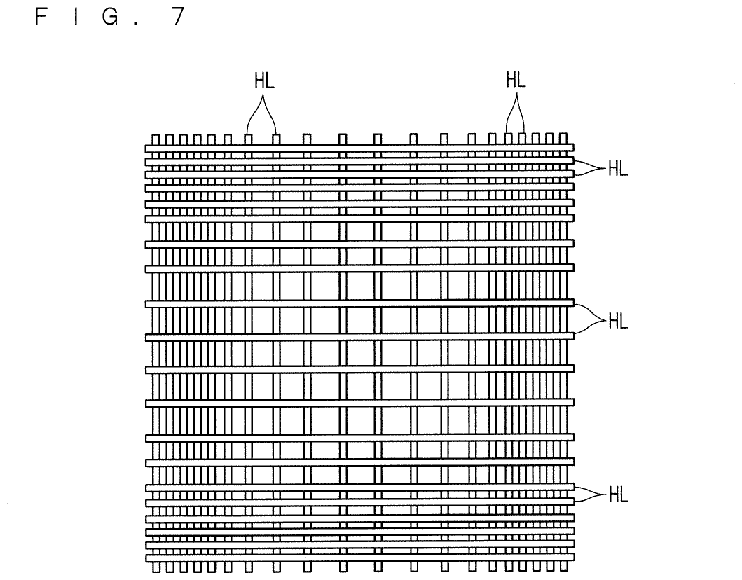

FIG. 7 is a plan view showing the arrangement of the plurality of halogen lamps HL. The 40 halogen lamps HL are arranged to be divided in two stages of upper and lower stages. Twenty halogen lamps HL are arranged in the upper stage near the holder 7, and twenty halogen lamps HL are arranged also in the lower stage farther from the holder 7 than the upper stage. Each halogen lamp HL is a rod-shaped lamp having a long cylindrical shape. The 20 halogen lamps HL in both the upper and lower stages are arranged so that the respective longitudinal directions are parallel to each other along the main surface of the GaN substrate W held by the holder 7 (that is, along the horizontal direction). Therefore, the plane formed by the arrangement of the halogen lamps HL in both the upper and lower stages is a horizontal plane.

In addition, as shown in FIG. 7, in both the upper and lower stages, the arrangement density of the halogen lamps HL in the region facing the circumferential edge portion is higher than that in the region facing the central portion of the mounting plate 91 held by the holder 7. That is, in both the upper and lower stages, the arrangement pitch of the halogen lamps HL is shorter in the circumferential edge portion than in the central portion of the lamp arrangement. Therefore, it is possible to apply a larger amount of light to the circumferential edge portion of the mounting plate 91 likely to have a temperature drop during heating by light irradiation from the halogen heating part 4.

In addition, the lamp group including the halogen lamps HL in the upper stage and the lamp group including the halogen lamps HL in the lower stage are arranged to intersect in a grid pattern. That is, a total of 40 halogen lamps HL are arranged so that the longitudinal direction of the 20 halogen lamps HL arranged in the upper stage and the longitudinal direction of the 20 halogen lamps HL arranged in the lower stage are orthogonal to each other.

The halogen lamp HL is a filament type light source that incandesces the filament and emits light by energizing the filament arranged inside the glass tube. Inside the glass tube, a gas in which a minute amount of a halogen element (iodine, bromine, or the like) is introduced into an inert gas such as nitrogen or argon is sealed. Introducing the halogen element makes it possible to set the temperature of the filament to a high temperature while suppressing the breakage of the filament. Therefore, the halogen lamp HL has a characteristic that it has a longer life and can continuously apply strong light as compared with a normal incandescent lamp. That is, the halogen lamp HL is a continuously lit lamp that continuously emits light for at least 1 second or longer. In addition, since the halogen lamp HL is a rod-shaped lamp, it has a long life, and arranging the halogen lamp HL along the horizontal direction causes the radiation efficiency to the mounting plate 91 arranged above to become excellent.

In addition, also inside the enclosure 41 of the halogen heating part 4, a reflector 43 is provided on the lower side of the two-stage halogen lamps HL (FIG. 1). The reflector 43 reflects the light emitted from the plurality of halogen lamps HL toward the heat treatment space 65.

The controller 3 controls the above-described various operating mechanisms provided in the heat treatment apparatus 1. The configuration of the controller 3 as hardware is the same as that of a general computer. That is, the controller 3 includes a CPU being a circuit that performs various types of arithmetic processing, a ROM being a read-only memory that stores basic programs, a RAM being a memory capable of reading and writing that stores various types of information, and a magnetic disc that stores control software, data, and the like. The CPU of the controller 3 executes a predetermined processing program, whereby the processing in the heat treatment apparatus 1 proceeds.

In addition to the above configuration, the heat treatment apparatus 1 has various cooling structures to prevent an excessive temperature rise of the halogen heating part 4, the flash heating part 5, and the chamber 6 due to the heat energy generated from the halogen lamps HL and the flash lamps FL during the heat treatment of the GaN substrate W. For example, a water cooling pipe (not shown) is provided on the wall of the chamber 6. In addition, the halogen heating part 4 and the flash heating part 5 have an air-cooling structure of forming a gas flow inside to exhaust heat. In addition, air is also supplied to the gap between the upper chamber window 63 and the lamp light radiation window 53 to cool the flash heating part 5 and the upper chamber window 63.

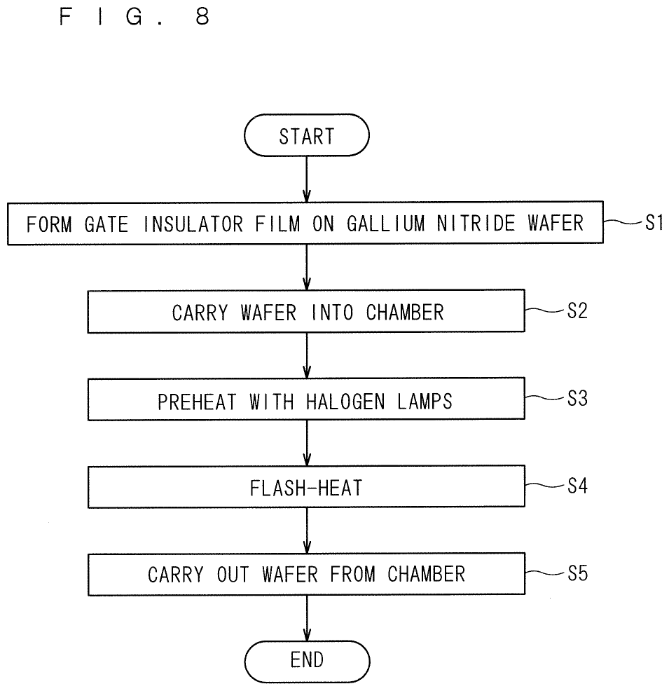

Next, a method for forming a gate insulator film according to the present invention will be described. FIG. 8 is a flowchart showing a procedure of the method for forming a gate insulator film according to the present invention. The GaN substrate W to be treated is a disc-shaped gallium nitride wafer having a diameter of about 50 mm (2 inches), which is significantly smaller than a typical silicon semiconductor wafer (300 mm in diameter). First, a gate insulator film is formed on the GaN substrate W to be treated (step S1). In the present embodiment, a gate insulator film of silicon dioxide (SiO₂) is formed on the GaN substrate W by CVD. The formation of the gate insulator film is performed using a CVD apparatus different from the heat treatment apparatus 1.

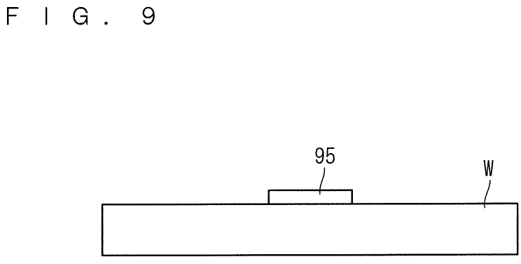

FIG. 9 is a diagram showing a state in which a gate insulator film 95 is formed on the GaN substrate W. When the gate insulator film 95 is formed on the GaN substrate W by CVD, a large number of traps exist at the interface between the gate insulator film 95 and GaN, and the Dit (Density of interface trap) is high. In addition, hydrogen is inevitably mixed in the gate insulator film 95 at the time of film formation, and the dielectric constant of the gate insulator film 95 is also low. Therefore, if this state is left unchanged, the characteristics of the gate insulator film 95 are low, so that a high-performance MOSFET cannot be manufactured. Therefore, in the heat treatment apparatus 1, post deposition annealing (PDA) is performed on the GaN substrate W on which the gate insulator film 95 is formed.

It is difficult for the heat treatment apparatus 1 to handle the small-diameter GaN substrate W having a diameter of about 50 mm as it is. Therefore, in the present embodiment, the small-diameter GaN substrate W is treated in the heat treatment apparatus 1 in a state of being placed on the mounting plate 91. FIG. 10 is a diagram showing a state in which the GaN substrate W is placed on the mounting plate 91. The mounting plate 91 is a disc-shaped member having a diameter of 300 mm. The mounting plate 91 is made of, for example, silicon carbide (SiC). Silicon carbide is an absorbent material having a high absorption rate for the light applied from the halogen lamp HL and the flash of light applied from the flash lamp FL.

A circular recessed portion having a diameter of about 70 mm is formed in the center of the upper surface of the mounting plate 91, and the GaN substrate W is placed so as to fit into the recessed portion. Placing the GaN substrate W in the recessed portion can prevent the positional deviation of the GaN substrate W. Then, the GaN substrate W in the state of being placed on the mounting plate 91 is heat-treated by the heat treatment apparatus 1. Since the size of the mounting plate 91 is about the same as that of a typical silicon semiconductor wafer, the heat treatment apparatus 1 for handling the silicon semiconductor wafer can heat-treat the GaN substrate W. Hereinafter, the heat treatment of the GaN substrate W in the heat treatment apparatus 1 will be described. The treatment procedure of the heat treatment apparatus 1 described below proceeds by controlling each operating mechanism of the heat treatment apparatus 1 by the controller 3.

Prior to the loading of the GaN substrate W, the air supply valve 84 is opened and the exhaust valve 89 is opened to start gas supply and exhaust to and from the inside of the chamber 6. When the air supply valve 84 is opened, nitrogen gas is supplied to the heat treatment space 65 from the gas supply opening 81. In addition, when the exhaust valve 89 is opened, the gas in the chamber 6 is exhausted from the gas exhaust opening 86. Thus, the nitrogen gas supplied from the upper portion of the heat treatment space 65 in the chamber 6 flows downward and is exhausted from the lower portion of the heat treatment space 65.

Subsequently, the GaN substrate W in a state of being placed on the mounting plate 91 is carried into the chamber 6 of the heat treatment apparatus 1 (step S2). Specifically, the gate valve 185 is opened, the transport opening 66 is opened, and the mounting plate 91 on which the GaN substrate W is placed is carried into the heat treatment space 65 in the chamber 6 through the transport opening 66 by a transport robot outside the apparatus. At this time, there is a risk that the atmosphere outside the apparatus may be sucked together with the loading of the GaN substrate W, but since nitrogen gas continues to be supplied to the chamber 6, nitrogen gas flows out from the transport opening 66, and such suction of external atmosphere can be minimized.

The mounting plate 91 carried in by the transfer robot advances to a position directly above the holder 7 and stops. Then, the pair of transfer arms 11 of the transfer mechanism 10 moves horizontally from the retracted position to the transfer operation position and rises, whereby the lift pins 12 protrude from the upper surface of the holding plate 75 of the susceptor 74 through the through holes 79 and receive the mounting plate 91 on which the GaN substrate W is placed. At this time, the lift pin 12 rises above the upper end of the support pin 77.

After the mounting plate 91 on which the GaN substrate W is placed is placed on the lift pins 12, the transfer robot exits the heat treatment space 65, and the transport opening 66 is closed by the gate valve 185. Then, as the pair of transfer arms 11 descends, the mounting plate 91 is transferred from the transfer mechanism 10 to the susceptor 74 of the holder 7 and held in a horizontal attitude from below. The mounting plate 91 is supported by a plurality of support pins 77 erected on the holding plate 75 and held by the susceptor 74. In addition, the mounting plate 91 is held by the holder 7 with the front surface of the GaN substrate W on which the gate insulator film 95 is formed facing the upper surface. A predetermined distance is formed between the back surface (the surface opposite to the surface on which the GaN substrate W is placed) of the mounting plate 91 supported by the plurality of support pins 77 and the holding surface 75a of the holding plate 75. The pair of transfer arms 11 lowered to below the susceptor 74 is retracted by the horizontal movement mechanism 13 to the retracted position, that is, inside the recessed portion 62.

After the mounting plate 91 is held from below in a horizontal attitude by the susceptor 74 of the holder 7 made of quartz, the 40 halogen lamps HL of the halogen heating part 4 are turned on all at once to start preheating (assist heating) (step S3). The halogen light emitted from the halogen lamps HL passes through the lower chamber window 64 and the susceptor 74 made of quartz and is applied to the lower surface of the mounting plate 91 on which the GaN substrate W is placed. Since the mounting plate 91 is made of SiC, the mounting plate 91 satisfactorily absorbs the light emitted from the halogen lamps HL and rises in temperature. Then, the GaN substrate W is preheated by thermal conduction from the heated mounting plate 91. It should be noted that since the transfer arms 11 of the transfer mechanism 10 are retracted inside the recessed portion 62, the transfer arms 11 do not hinder heating by the halogen lamps HL.

When the halogen lamps HL perform preheating, the temperature of the mounting plate 91 on which the GaN substrate W is placed is measured by the radiation thermometer 20. That is, the radiation thermometer 20 receives infrared light radiated through the opening 78 from the lower surface of the mounting plate 91 held by the susceptor 74 through the transparent window 21 and measures the temperature of the mounting plate 91 during temperature rise. The measured temperature of the mounting plate 91 is transmitted to the controller 3. The controller 3 controls the output of the halogen lamps HL while monitoring whether the temperature of the mounting plate 91 to be raised by light irradiation from the halogen lamps HL has reached a target temperature

T1. That is, the controller 3 feedback-controls the output of the halogen lamps HL so that the temperature of the mounting plate 91 reaches the target temperature T1 based on the measured value by the radiation thermometer 20. The target temperature T1 is 600° C. or higher and 800° C. or lower.

After the temperature of the mounting plate 91 reaches the target temperature T1, the controller 3 adjusts the output of the halogen lamps HL so that the temperature of the mounting plate 91 maintains the target temperature T1. Specifically, when the temperature of the mounting plate 91 measured by the radiation thermometer 20 reaches the target temperature T1, the controller 3 adjusts the output of the halogen lamps HL and maintains the temperature of the mounting plate 91 at almost the target temperature T1. Maintaining the mounting plate 91 at the target temperature T1 by light irradiation from the halogen lamps HL uniformly preheats the GaN substrate W by thermal conduction from the mounting plate 91.

When a predetermined time elapses after the temperature of the mounting plate 91 reaches the target temperature T1, the front surface of the GaN substrate W is irradiated with a flash of light from the flash lamps FL of the flash heating part 5 (step S4). At this time, part of the flash of light radiated from the flash lamps FL goes directly into the chamber 6, the other part is once reflected by the reflector 52 and then goes into the chamber 6, and irradiation with these flashes of light flash-heats the GaN substrate W.

Since the flash heating is performed by applying a flash of light (flash) from the flash lamps FL, the front surface temperature of the GaN substrate W can be raised in a short time. That is, a flash of light applied from the flash lamps FL is an extremely short and strong flash with an irradiation time of about 0.1 ms or more and 100 ms or less obtained by converting the electrostatic energy stored in advance in the capacitor into an extremely short optical pulse. Then, the front surface of the GaN substrate W including the gate insulator film 95 is instantaneously raised to the treatment temperature T2 by a flash of light irradiation from the flash lamps FL, and then rapidly lowered. The treatment temperature T2 being the maximum reaching temperature of the gate insulator film 95 during flash heating is higher than the above target temperature T1 and is 800° C. or higher and 1200° C. or lower. Instantaneously heating the surface of the GaN substrate W to the treatment temperature T2 performs post deposition annealing on the gate insulator film 95 and reduces the traps existing at the interface between the gate insulator film 95 and GaN.

Here, even if the GaN substrate W on which the gate insulator film 95 is formed is heated to the treatment temperature T2 using rapid thermal annealing (RTA) being a typical method for post deposition annealing, it is possible to reduce the traps existing at the interface between the gate insulator film 95 and GaN. However, heating the GaN substrate W to the treatment temperature T2 using RTA causes a phenomenon to occur in which nitrogen is desorbed from the GaN and the unbonded gallium diffuses into the gate insulator film 95. As a result, deterioration in insulating characteristics (increase in leakage current, decrease in dielectric breakdown field, and the like) occurs in the gate insulator film 95. It should be noted that although the preheating by the halogen lamps HL described above is also a kind of RTA, since the target temperature T1 is lower than the treatment temperature T2, nitrogen does not desorb from GaN during preheating and traps do not decrease. That is, it can be said that there is a trade-off relationship between the reduction of traps and the prevention of nitrogen desorption from GaN.

In the present embodiment, irradiating the GaN substrate W with a flash of light having an irradiation time of less than 1 second flash-heats the front surface of the GaN substrate W including the gate insulator film 95 from the target temperature T1 to the treatment temperature T2 in an extremely short heat treatment time. Therefore, the time during which the GaN substrate W is at a high temperature is short, and the desorption of nitrogen from the GaN can be suppressed to a minimum. As a result, it is possible to reduce the traps existing at the interface between the gate insulator film 95 and GaN without diffusing gallium in the gate insulator film 95 to reduce Dit. In addition, flash-heating the GaN substrate W makes it also possible to reduce the hydrogen mixed in the gate insulator film 95 at the time of film formation and increase the dielectric constant of the gate insulator film 95. Thus, a high-performance MOSFET using gallium nitride can be manufactured.

After the flash heating treatment is completed, the halogen lamps HL turn off after the elapse of a predetermined time. Thus, the temperature of the GaN substrate W and the mounting plate 91 drops rapidly. The temperature of the mounting plate 91 during dropping in temperature is measured by the radiation thermometer 20, and the measurement result is transmitted to the controller 3. The controller 3 monitors whether the temperature of the mounting plate 91 has dropped to a predetermined temperature based on the measurement result of the radiation thermometer 20. Then, after the temperature of the mounting plate 91 drops to a predetermined temperature or less, the pair of transfer arms 11 of the transfer mechanism 10 horizontally moves from the retracted position to the transfer operation position again and rises, whereby the lift pins 12 protrude from the upper surface of the susceptor 74 and receive the mounting plate 91 on which the heat-treated GaN substrate W is placed from the susceptor 74. Subsequently, the transport opening 66 closed by the gate valve 185 is opened, the mounting plate 91 placed on the lift pins 12 is carried out by a transfer robot outside the apparatus, and heating treatment of the GaN substrate W in the heat treatment apparatus 1 is completed (step S5). A metal gate electrode such as aluminum is formed on the gate insulator film 95 of the GaN substrate W that has been heat-treated by the heat treatment apparatus 1.

In the present embodiment, irradiating with a flash of light having an irradiation time of 0.1 ms or more and 100 ms or less flash-heats the front surface of the GaN substrate W including the gate insulator film 95 to the treatment temperature T2 in an extremely short heat treatment time. Thus, the desorption of nitrogen from the GaN substrate W can be prevented and it is possible to reduce the traps existing at the interface between the gate insulator film 95 and GaN without diffusing gallium into the gate insulator film 95. That is, irradiating with a flash of light having an extremely short irradiation time makes it possible to achieve both reduction in traps and prevention of nitrogen desorption from GaN.

Although the embodiments of the present invention have been described above, the present invention can be changed in various ways in addition to those described above without departing from the spirit of the present invention. For example, in the above embodiment, the GaN substrate W is heated by flash lamp annealing that applies a flash of light having an irradiation time of less than 1 second, but instead of this, the front surface of the GaN substrate W including the gate insulator film 95 may be heated to the treatment temperature T2 by laser annealing. The heat treatment time by laser annealing is even shorter than that of flash lamp annealing, and can be 10 ns at the shortest. Since the heat treatment time by laser annealing is also extremely short, it is possible to reduce the traps existing at the interface between the gate insulator film 95 and GaN without diffusing gallium in the gate insulator film 95 as in the case of flash lamp annealing. In short, if the front surface of the GaN substrate W including the gate insulator film 95 is heated in an extremely short heat treatment time of 10 ns or more and 100 ms or less, similarly to the above embodiment, it is possible to achieve both reduction in traps and prevention of nitrogen desorption from GaN.

In addition, in the above embodiment, the gate insulator film 95 made of silicon dioxide is formed on the GaN substrate W, but the present invention is not limited to this, and the gate insulator film made of gallium oxide (GaOx) may be formed on the GaN substrate W. The gate insulator film made of gallium oxide is formed on the GaN substrate W by a thermal oxidation method. There are also a large number of traps at the interface between the gate insulator film made of gallium oxide formed by the thermal oxidation method and GaN. Then, as in the above embodiment, heating the front surface of the GaN substrate W including the gate insulator film made of gallium oxide in an extremely short heat treatment time makes it possible to reduce the traps without diffusing gallium into the gate insulator film.

In addition, the size of the GaN substrate W is not limited to about 50 mm in diameter, and may be, for example, about 100 mm (4 inches) in diameter.

In addition, the quality of material of the mounting plate 91 is not limited to silicon carbide, and may be, for example, silicon (Si). However, if the GaN substrate W is heated to a high temperature of about 1400° C. during flash heating, the silicon (melting point 1414° C.) mounting plate 91 may melt, so that the mounting plate 91 is preferably made of silicon carbide (melting point 2730° C.).

In addition, in the above embodiment, the flash heating part 5 is provided with 30 flash lamps FL, but the present invention is not limited to this, and the number of flash lamps FL can be any number. In addition, the flash lamp FL is not limited to the xenon flash lamp, and may be a krypton flash lamp. In addition, the number of halogen lamps HL provided in the halogen heating part 4 is not limited to 40 either, and can be any number.

In addition, in the above embodiment, the GaN substrate W is preheated using the filament type halogen lamp HL as a continuously lit lamp that continuously emits light for 1 second or longer, but the present invention is not limited to this, and instead of the halogen lamp HL, a discharge type arc lamp (for example, xenon arc lamp) may be used as a continuously lit lamp to perform preheating.

### EXPLANATION OF REFERENCE SIGNS

1: heat treatment apparatus

3: controller

4: halogen heating part

5: flash heating part

6: chamber

7: holder

10: transfer mechanism

65: heat treatment space

74: susceptor

75: holding plate

77: support pin

91: mounting plate

95: gate insulator film

FL: flash lamp

HL: halogen lamp

W: GaN substrate

1. A method for forming a gate insulator film, the method comprising:
a film forming step of forming a gate insulator film made of silicon dioxide or gallium oxide on a substrate made of gallium nitride; and
an annealing step of heating said substrate and said gate insulator film for a heat treatment time of 10 ns or more and 100 ms or less.

2. The method for forming a gate insulator film according to claim 1, wherein a maximum reaching temperature of said gate insulator film in said annealing step is 800° C. or higher and 1400° C. or lower.

3. A heat treatment method comprising:
a loading step of loading a substrate made of gallium nitride on which a gate insulator film made of silicon dioxide or gallium oxide is formed into a chamber; and
a light irradiation step of irradiating a surface of said substrate with a flash of light from a flash lamp for an irradiation time of less than 1 second to heat said surface and said gate insulator film.

4. The heat treatment method according to claim 3, wherein a maximum reaching temperature of said gate insulator film in said light irradiation step is 800° C. or higher and 1400° C. or lower.

5. The heat treatment method according to claim 3, further comprising a preheating step of preheating said substrate to 600° C. or higher and 800° C. or lower by light irradiation from a continuously lit lamp before said light irradiation step.

6. A heat treatment method comprising:
a loading step of loading a substrate made of gallium nitride on which a gate insulator film made of silicon dioxide or gallium oxide is formed into a chamber; and
an annealing step of heating said substrate and said gate insulator film for a heat treatment time of 10 ns or more and 100 ms or less.
